(19) United States
(12) Patent Application Publication
(10) Pub. No.: US 2014/0130858 A1
(43) Pub. Date: May 15, 2014

(54) SOLAR CELL

(71) Applicant: SAMSUNG SDI CO., LTD., Yongin-si (KR)

(72) Inventor: Seung-Jae Jung, Yongin-si (KR)

(73) Assignee: SAMSUNG SDI CO., LTD., Yongin-si (KR)

(21) Appl. No.: 14/032,135

(22) Filed: Sep. 19, 2013

Related U.S. Application Data
(60) Provisional application No. 61/726,982, filed on Nov. 15, 2012.

(51) Int. Cl. H01L 31/0224; H01L 31/18

(52) U.S. Cl. CPC H01L 31/022466; H01L 31/1884
USPC 136/256; 438/95

(57) ABSTRACT

A solar cell including a substrate, a first electrode layer in which a 1a-th through-region is formed, a second electrode layer in which a 1b-th through-region is formed at a position corresponding to the 1a-th through-region, and a light absorbing layer formed on the second electrode layer. Here, the solar cell can be implemented to be thin and have improved power generating efficiency.

### CROSS-REFERENCE TO RELATED APPLICATION

This application claims priority to and the benefit of U.S. Provisional Application No. 61/726,982, filed on Nov. 15, 2012 in the U.S. Patent and Trademark Office, the entire content of which is incorporated herein by reference.

### BACKGROUND

1. Field

The present disclosure relates to a solar cell.

2. Description of the Related Art

As demands on energy increase, demands on solar cells for converting sunlight energy into electrical energy increase. Solar cells are clean energy sources that produce electricity from the sun. Solar cells have come into the spotlight as new growth engines with a high industrial growth rate every year.

A copper-indium-gallium-(di)selenide (CIGS) solar cell is a solar cell that can be implemented as a thin film and does not use Si. Thus, it is expected that the CIGS solar cell will play an important role in spreading use of sunlight energy by lowering production cost of solar cells. Further, it is known that since the CIGS solar cell is thermally stable, a decrease in efficiency with time is small. Therefore, various studies have been conducted to increase power-generating capacity of the CIGS solar cell. Particularly, a plan should be proposed for improving power-generating capacity while fabricating a thin CIGS solar cell.

### SUMMARY

Aspects of embodiments of the present invention are directed toward a solar cell capable of improving power generation efficiency while being implemented to be thin.

In an embodiment, a solar cell is provided. The solar cell includes a substrate, a first electrode layer on the substrate, a second electrode layer on the first electrode layer, and a light absorbing layer on the second electrode layer. In this embodiment, the first electrode layer has a first through-region, the second electrode layer is a transparent electrode layer and has a second through-region, and the second through-region is narrower than the first through-region and is at a position corresponding to the first through region.

In one embodiment, the second electrode layer covers an upper surface and a side surface of the first electrode layer, and the side surface is inside the first through-region.

In one embodiment, the second electrode layer covers a portion of the upper surface of the substrate by a distance equal to a thickness of the second electrode layer.

In one embodiment, the second electrode layer covers a portion of the upper surface of the substrate by a distance greater than a thickness of the second electrode layer.

In one embodiment, the light absorbing layer contacts at least a portion of the substrate.

In one embodiment, the difference in a width of the first through-region and a width of the second through-region is less than the width of the first through-region.

In one embodiment, the difference in a width of the first through-region and a width of the second through-region is 10 μm or more.

In one embodiment, the difference in a width of the first through-region and a width of the second through-region is 30 μm or more.

In one embodiment, the first electrode layer is a back surface electrode layer, and includes at least one selected from Ag, Al, Cu, Au, Pt and Cr.

In one embodiment, the light absorbing layer includes a Group I-III-VI based compound semiconductor or a Group I-II-IV-VI based compound semiconductor.

In one embodiment, the light absorbing layer includes at least one selected from Cu, In, Ga, S, Se, Zn, and Sn.

In one embodiment, the second electrode layer includes at least one selected from zinc oxide, indium oxide, tin oxide, titanium oxide, and zinc oxide doped with one or more of Al, Ga and B.

In one embodiment, the second electrode layer has a thickness of at least 10 nm or a thickness of from 50 to 150 nm.

In one embodiment, the solar cell further includes at least one selected from an adhesion improving layer between the first electrode layer and the substrate, a diffusion barrier layer between the first electrode layer and the substrate, a contact resistance improving layer between the second electrode layer and the light absorbing layer, a buffer layer on the light absorbing layer, and a rear surface electrode layer on a buffer layer on the light absorbing layer.

In one embodiment, the adhesion improving layer includes at least one selected from Ti, Cr, Mo and Ni.

In one embodiment, the diffusion barrier layer includes an oxide or nitride material selected from silicon oxide, silicon nitride, silicon oxynitride, aluminum oxide, aluminum oxynitride, titanium nitride, tantalum nitride, and tungsten nitride.

In one embodiment, the contact resistance improving layer includes at least one of MSeₓ or MSₓ, wherein M is selected from Mo, W, Ta, Nb, Ti, Cr, V and Mn.

In one embodiment, the solar cell has a thickness of less than 1 μm.

In another embodiment, a method of making a solar cell is provided. The method includes: forming a first electrode layer on a substrate; forming a first through-region through the first electrode layer, to expose a first portion of the substrate; forming a second electrode layer covering the first electrode layer and the exposed first portion of the substrate; and forming a second through-region through the second electrode layer in a region of the second electrode layer which is inside the first through region, to expose a second portion of substrate; forming a light absorbing layer covering the second electrode layer and the exposed second portion of the substrate.

In one embodiment, at least one of the forming of the through-region of the first electrode layer or the forming of the through-region of the second electrode layer includes patterning the first electrode layer or the second electrode layer, respectively.

In one embodiment, the first electrode layer is formed through a sputtering process, a deposition process, a plating process, or a screen printing process.

In one embodiment, the second electrode layer is formed through a sputtering process, a deposition process, or a chemical vapor deposition (CVD) process.

Other features and advantages of the present invention will become more apparent from the following detailed description, taken in conjunction with the accompanying drawings.

Terms or words used in this specification and claims should not be restrictively interpreted as ordinary meanings or dictionary-based meanings, but should be interpreted as meanings and concepts conforming to the scope of the present disclosure.

Aspects of embodiments of the present disclosure are directed toward a solar cell, which allows, in some embodiments, to implement a thin solar cell and to improve power generating efficiency by forming a transparent electrode layer between a back surface electrode layer and a light absorbing layer.

In one embodiment, the back surface electrode layer is configured as a high reflection electrode, thereby improving a re-absorption rate of the solar cell.

In one embodiment, the exposed back surface electrode layer is covered with the transparent electrode layer, so that it is possible to prevent (or reduce) selenization of the back surface electrode layer. Accordingly, in some embodiments, it is possible to prevent a decrease in resistance of the back surface electrode layer, a peeling phenomenon and/or a defect caused by diffusion of the high reflection electrode into the light absorbing layer.

### BRIEF DESCRIPTION OF THE DRAWINGS

The accompanying drawings, together with the specification, illustrate embodiments of the present invention, and, together with the description, serve to explain the principles of the present invention by way of example.

FIG. 1 is a cross-sectional view of a solar cell according to an embodiment of the present invention.

FIGS. 2 and 3 are cross-sectional views comparing solar cells with the solar cell shown in FIG. 1.

FIGS. 4 to 6 are cross-sectional views illustrating a method of fabricating the solar cell shown in FIG. 1.

FIG. 7 is a cross-sectional view of a solar cell according to another embodiment of the present invention.

FIGS. 8 to 11 are cross-sectional views of solar cells according to further embodiments of the present invention.

### DETAILED DESCRIPTION

In the following detailed description, only certain embodiments of the present invention have been shown and described, by way of example. As those skilled in the art would realize, the described embodiments may be modified in various different ways, all without departing from the spirit or scope of the present invention. Accordingly, the drawings and description are to be regarded as illustrative in nature and not restrictive. In addition, when an element is referred to as being “on” another element, it can be directly on the other element or can be indirectly on the other element with one or more intervening elements interposed therebetween. Also, when an element is referred to as being “connected to” another element, it can be directly connected to the other element or can be indirectly connected to the other element with one or more intervening elements interposed therebetween. Hereinafter, like reference numerals refer to like elements.

Hereinafter, embodiments of the present invention will be described in more detail with reference to the accompanying drawings.

According to an embodiment of the present disclosure, a solar cell is provided, which includes a substrate, a first electrode layer on the substrate, a second electrode layer on the first electrode layer; and a light absorbing layer on the second electrode layer. In this embodiment, the first electrode layer has a first through-region, the second electrode layer has a second through-region, and the second through-region is narrower than the first through-region and is at a position corresponding to the first through region. In one embodiment, the second electrode layer is a transparent electrode layer. In one embodiment, the first electrode layer is a back surface electrode layer.

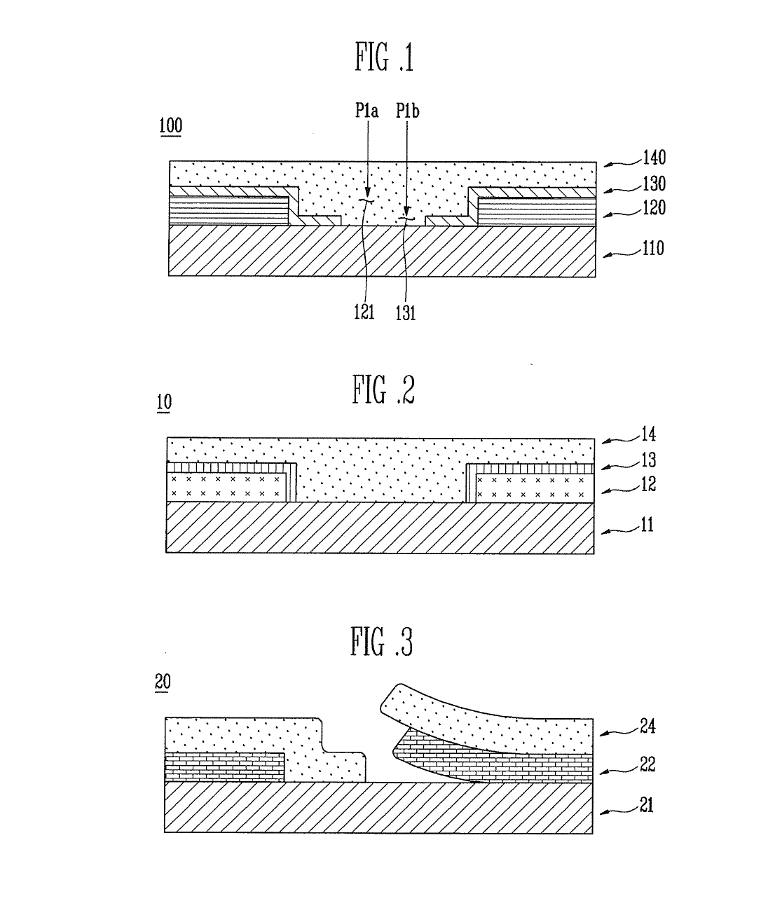

FIG. 1 is a cross-sectional view of a solar cell 100 according to an embodiment of the present invention. Hereinafter, the solar cell 100 according to this embodiment will be described with reference to FIG. 1.

As shown in FIG. 1, the solar cell 100 according to this embodiment sequentially includes a substrate 110, a first electrode layer 120in which a 1a-th through-hole 121 is formed, a second electrode layer 130, in which a 1b-th through-hole 131 is formed, and a light absorbing layer 140. In one embodiment, the second electrode layer 130 is a transparent electrode layer 130. In one embodiment, the first electrode layer 120 is a back surface electrode layer 120.

According to some embodiments, the substrate 110 is a member that provides a base on which the back surface electrode layer 120 and the transparent electrode layer 130 are formed. That is, in one embodiment, the substrate 110 is the base of the solar cell 100.

In one embodiment, the substrate 110 is a glass substrate, ceramic substrate, metal substrate, or polymer substrate. For example, in one embodiment, the substrate 110 is a glass substrate including alkali elements such as Na, K or Cs. In some embodiments, the substrate 110 is a sodalime glass substrate or high strained point soda glass substrate.

In some embodiments, the back surface electrode layer 120 is a member which is formed on the substrate 110, and includes the 1a-th through-region 121.

In one embodiment, the 1a-th through-hole 121 is formed in the back surface electrode layer 120 through a patterning process. The term “through-region” as used herein (e.g. in referring to the 1a-th through-region 121) refers to a through-hole or a space in which inner walls of the patterned back surface electrode layers 120 defining the through-hole or the space, are spaced apart from each other. In one embodiment the back surface electrode layer 120 is made of metal having good stability at a high temperature and high electrical conductivity. In this embodiment, the back surface electrode layer 120 is made of high reflection metal such as Ag, Al, Cu, Pt or Cr. In some embodiments, an particularly in embodiments where the high reflection metal is used as the back surface electrode layer 120, the reflectivity of light transmitted into the solar cell 100 is high even though the solar cell 100 is implemented to be thin. Thus, in some embodiments, the amount of light reabsorbed in the solar cell 100 increases, thereby reducing current loss.

In some embodiments, the transparent electrode layer 130 is a member formed on the back surface electrode layer 120 having the 1a-th through-region 121 formed therein.

In one embodiment, the 1b-th through-region 131 is formed in the transparent electrode layer 130 through a patterning process. In one embodiment, the 1b-th through-region 131 is formed at a position corresponding to the 1a-th through-region 121. In one embodiment, a portion of the substrate 110 is exposed by the 1b-th through-region 131, so as to contact the light absorbing layer 140. In some embodiments, the width of the 1b-th through-region 131 is narrower than that of the 1a-th through-region 121. That is, in these embodiments, a width along a direction that spaces apart inner walls of the patterned back surface electrode layers 120 (e.g. the 1a-th through-region 121) defining the through-hole or the space, is larger than a width of the 1b-th through-region 131 along the same direction. To put it another way, the width is along a direction that spaces apart the inner walls of the transparent electrode. In one embodiment, the difference in a width of the 1a-th through-region 121 and a width of the 1b-th through-region 131 is less than the width of the 1a-th through-region 121. In one embodiment, the difference in width between the 1a-th through-region 121 and the 1b-th through-region 131 is 10 μm or more. In another embodiment, the difference in width between the 1a-th through-region 121 and the 1b-th through-region 131 is 30 μm or more. In some embodiments, and particularly in embodiments where the width of the 1b-th through-region 131 is narrower than that of the 1a-th through-region 121 as described above, the transparent electrode layer 130 is positioned to extend to the upper surface of the back surface electrode layer 120, the side surface of the back surface electrode layer 120, exposed by the 1a-th through-region 121, and a portion of the upper surface of the substrate 110, exposed by the 1a-th through-region 121. In some of these embodiments, the transparent electrode layer 130 is positioned at a portion adjacent to the back surface electrode layer 120 on the upper surface of the substrate 110, such that the 1b-th through-region 131 is positioned to correspond to the 1a-th through-region 121. In one embodiment, the transparent electrode layer 130 is formed to have, for example, a thickness of 50 to 150 nm. In one embodiment, the thickness of the transparent electrode layer 130 positioned at the exposed side surface of the back surface electrode layer 120 is, for example, 10 nm or more in order to prevent or reduce a selenization reaction between the back surface electrode layer 120 and the light absorbing layer 140.

Although it has been described in this embodiment that the width of the 1b-th through-region 131 is narrower by 10 μm or more than that of the 1a-th through-region 121, and therefore, the transparent electrode layer 130 is extended up to the exposed upper surface of the substrate 110, the present invention is not limited thereto. For example, embodiments where the width of the 1b-th through-region 131 is implemented to be slightly narrower than that of the 1a-th through-region 121, so that the transparent electrode layer 130 is formed on only the upper and side surfaces of the back surface electrode layer 120 are included within the scope of the present invention. For example, in some embodiments, the second electrode layer covers a portion of the upper surface of the substrate by a distance equal to a thickness of the second electrode layer (e.g. as shown in FIG. 2) and, in other embodiments, the second electrode layer covers a portion of the upper surface of the substrate by a distance greater than a thickness of the second electrode layer (e.g. as shown in FIG. 1).

In one embodiment, a transparent and conductive material is used for the transparent electrode layer 130, which in some embodiments, allows for improvement of reflectivity and refractive index. In some embodiments, the transparent electrode layer 130 is made of a transparent conductive oxide (TOC), for example, zinc oxide, indium oxide, tin oxide, titanium oxide, and/or zinc oxide doped with one or more of Al, Ga, and/or B (e.g. ZnO; ZnO doped with Al, Ga, and/or B; In₂O₃; SnO₂; and/or TiO₂).

In one embodiment, the light absorbing layer 140 is a member which is formed on the transparent electrode layer 130 having the 1b-th through-region 131 formed therein.

In one embodiment, the light absorbing layer 140 is a portion of the solar cell absorbing light. In one embodiment, the light absorbing layer includes at least one selected from Cu, In, Ga, S, Se, Zn, and Sn. In one embodiment, the light absorbing layer is formed of a Group I-III-VI based compound semiconductor or Group I-II-IV-VI based compound semiconductor. Examples of the Group I element according to some embodiments include Cu, Ag, and Au. Examples of the Group II element according to some embodiments include Zn and Cd. Examples of the Group III element according to some embodiments include In, Ga, and Al. Examples of the Group IV element according to some embodiments include Si, Ge, Sn, and Pb. Examples of the Group VI element according to some embodiments include S, Se, and Te.

Specifically, examples of the Group I-III-VI based compound semiconductor include a compound semiconductor such as CIS, CGS or CIGS (here, C denotes copper (Cu), I denotes indium (In), G denotes gallium (Ga), and S denotes one or more of sulfur (S) and selenium (Se)). An example of the Group I-II-IV-VI based compound semiconductor is a compound semiconductor such as CZTS (here, C denotes copper (Cu), Z denotes zinc (Zn), T denotes tin (Sn), and S denotes one or more of sulfur (S) and selenium (Se)).

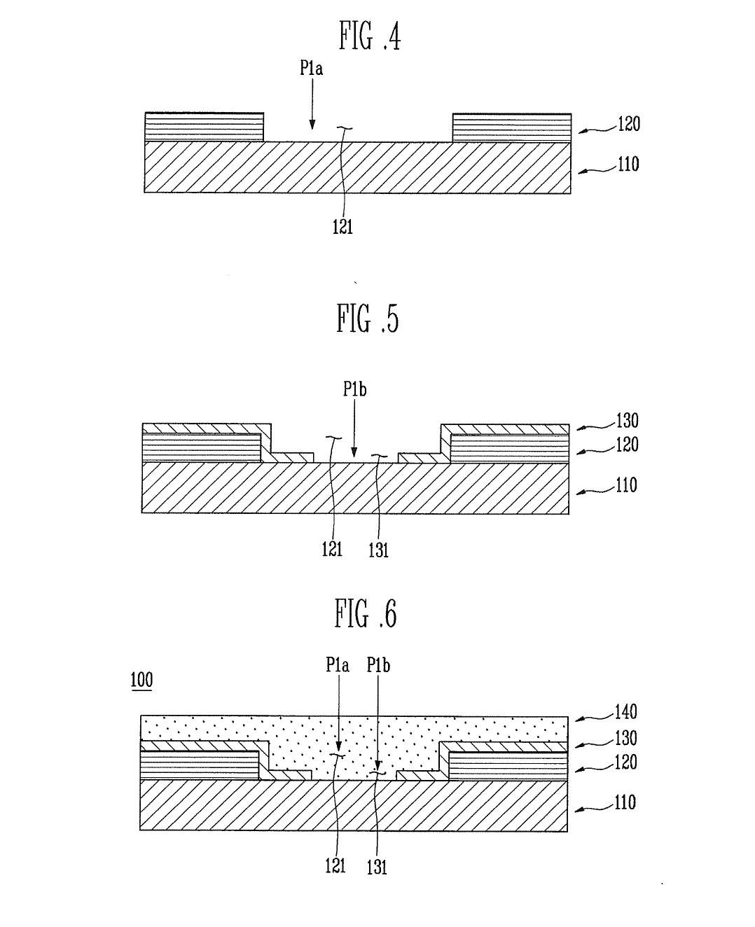

FIGS. 2 and 3 are cross-sectional views comparing solar cells (10 and 20) with the solar cell 100 shown in FIG. 1. Hereinafter, the solar cell 100 according to this embodiment will be described in more detailed with reference to FIGS. 2 and 3.

As shown in FIG. 2, in one embodiment, a general back surface electrode layer 12 formed on a substrate 11 of a solar cell 10 is made of molybdenum (Mo). Here, the Mo is stable under the selenization atmosphere of a light absorbing layer 14, but the reflectivity of the Mo is relatively low. Therefore, in a case where the thickness of the solar cell 10 is implemented to be thin, the re-absorption of light is reduced. Particularly, in a case where the solar cell 10 is implemented to have a thickness of 1 μm or less, current loss of a few mA/cm² is expected. Here, reference numeral 13 denotes an alloy layer, and in an embodiment, corresponds to a layer formed by a selenization reaction between the Mo and the light absorbing layer 14.

In an embodiment, in order to improve re-absorption, a solar cell 20 includes a high reflection metal such as Ag as a back surface electrode layer 22, which is formed on a substrate 21 as shown in FIG. 3. However, the high reflection metal such as Ag is unstable under a selenization atmosphere of 400° C. or more, and therefore, the entire back surface electrode layer 22 may be transferred into AgSeₓ. In a case where the entire back surface electrode layer 22 is transferred into AgSeₓ, the resistance of the back surface electrode layer 22 is lost, and the AgSeₓ has a low adhesive property with the substrate 21. As shown in FIG. 3, the peeling phenomenon may occur in a subsequent process. The Ag of the back surface electrode layer 22 is diffused in a light absorbing layer 24 configured with CIGS, and therefore, a defect may occur in the light absorbing layer 24.

The solar cell 100 according to an embodiment is derived at least in part, from the above considerations, and aspects of embodiments of the present invention, for example, the solar cell 100 as shown in FIG. 1, are directed toward overcoming the aforementioned problems.

Specifically, although the solar cell 100 according to embodiments of the present disclosure is implemented to have a thickness of 0.5 μm or less using high reflection metal such as Ag or Al as the back surface electrode layer 120, current loss is low, thereby increasing a re-absorption rate of light. In one embodiment, the transparent electrode layer 130 is formed after the 1a-th through-region 121 is formed in the back surface electrode layer 120, and thus it is possible, in embodiments of the present disclosure, to prevent or substantially prevent the back surface electrode layer 120 and the light absorbing layer 140 from coming in direct contact with each other. In these embodiments, the transparent electrode layer 130 is formed not only on the upper surface of the back surface electrode layer 120 but also on the exposed side surface of the back surface electrode layer 120, so that it is possible to prevent or substantially prevent, in advance, the high reflection metal such as Ag and the Se of the light absorbing layer 140 from reacting with each other through the exposed side surface of the back surface electrode layer 120. Thus, it is possible, in some embodiments, to prevent or substantially prevent, in advance, the entire back surface electrode layer 120 from being transferred into AgSeₓ due to the reaction between Se and Ag through the exposed side surface of the back surface electrode layer 120. Accordingly, it is possible to prevent or reduce resistance loss due to the transfer of the back surface electrode layer into AgSeₓ, occurrence of a peeling phenomenon, and/or occurrence of a defect.

In one embodiment, the transparent electrode layer 130 is also formed on the upper surface of the substrate 110, exposed by the 1a-th through-region 121, because, for example, the width of the 1a-th through-region 121 is wider than that of the 1b-th through-region 131. In embodiments where the transparent electrode layer 130 is formed to extend up to the upper surface of the substrate 110, it is possible to more certainly prevent or reduce the high reflection metal from reacting with the Se of the light absorbing layer 140.

FIGS. 4 to 6 are cross-sectional views illustrating a fabricating method of the solar cell 100 shown in FIG. 1. Hereinafter, the fabricating method of the solar cell 100 according to this embodiment will be described with reference to FIGS. 4 to 6.

First, as shown in FIG. 4, a patterned back surface electrode layer 120 is formed on the upper surface of a substrate 110.

In some embodiments, a 1a-th through region 121 is formed in the back surface electrode layer through a patterning process, and a portion of the upper surface of the substrate 110 is exposed to the outside by the 1a-th through-region 121. In some embodiments, the back surface electrode layer 120 is formed through a sputtering process, a deposition process, a plating process, and/or a screen printing process. In some embodiments, the 1a-th through-region 121 is formed through, for example, a laser process.

Next, as shown in FIG. 5, a transparent electrode layer 130 is formed on the back surface electrode layer 120 having the 1a-th through-region 121 formed therein.

In some embodiments, a 1b-th through-region 131 is formed in the transparent electrode layer 130 through a patterning process. In some embodiments, the 1b-th through-region 131 is formed to correspond to the position at which the 1a-th through-region 121 is formed. In some embodiments, the transparent electrode layer 130 is formed through a sputtering process, a deposition process, or a chemical vapor deposition (CVD) process. In some embodiments, the 1b-th through-region 131 is formed through a laser process. In some embodiments, the width of the 1b-th through-region 131 is narrower by 10 μm or more or narrower by 30 μm or more, compared to that of the 1a-th through-region 121, for example, depending on mechanical tolerance according to the laser process.

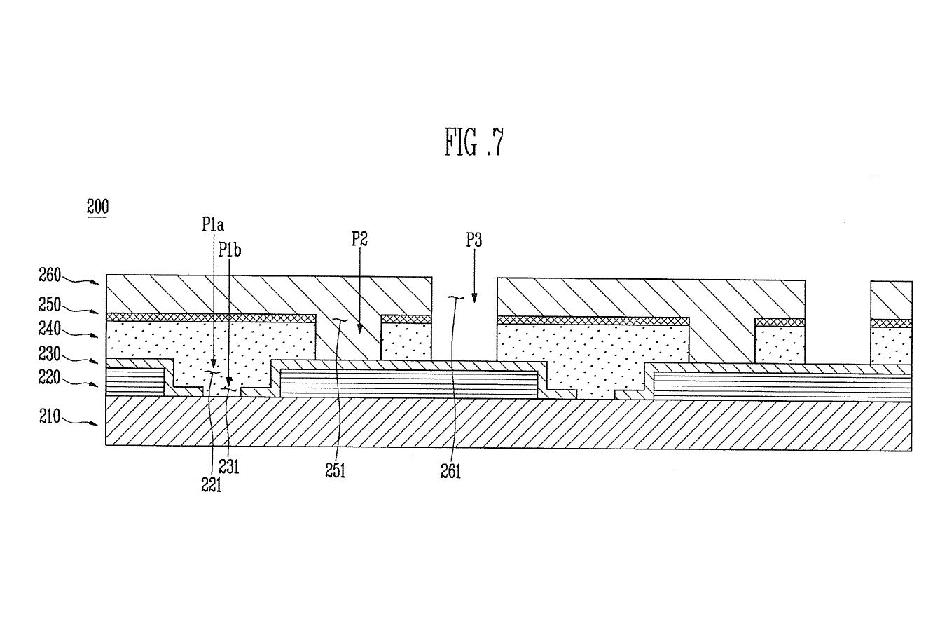

Next, as shown in FIG. 6, according to one embodiment, a light absorbing layer 140 is formed on the transparent electrode layer 130 having the 1b-th through-region 131 formed therein, thereby fabricating the solar cell 100.

FIG. 7 is a cross-sectional view of a solar cell 200 according to another embodiment of the present invention. Hereinafter, the solar cell 200 according to this embodiment will be described with reference to FIG. 7.

As shown in FIG. 7, the solar cell 200 according to this embodiment includes a substrate 210, a back surface electrode layer 220 in which a 1a-th through-region is formed, a transparent electrode layer 230 in which a 1b-th through-region 231 is formed, and a light absorbing layer 240, as shown in FIG. 1. In some embodiments, the solar cell 200 further includes a buffer layer 250 and a rear surface electrode layer 260.

In some embodiments, the buffer layer 250 is formed with at least one layer on the light absorbing layer 240. Here, the light absorbing layer 240 formed beneath the buffer layer 250 acts as a p-type semiconductor, and the rear surface electrode layer 260 formed on the buffer layer 250 acts as an n-type semiconductor, so that a p-n junction can be formed between the light absorbing layer 240 and the rear surface electrode layer 260. In these embodiment, the buffer layer 250 is formed to have a bandgap at a middle level between those of the light absorbing layer 240 and the rear surface electrode layer 260, so that an good junction between the light absorbing layer 240 and the rear surface electrode layer 260 can be implemented. In one embodiment, the buffer layer 250 is made, for example, of CdS or ZnS. In some embodiments, the buffer layer 250 is patterned together with the light absorbing layer 240. Accordingly, in some embodiments, the buffer layer 250 includes a second through-region 251.

In some embodiments, the rear surface electrode layer 260 is formed on the buffer layer 260. In one embodiment, the rear surface electrode layer 260 is a conductive layer and acts as an n-type semiconductor. For example, in one embodiment, the rear surface electrode layer 260 is made of a transparent conductive oxide (TOC). In one embodiment, the rear surface electrode layer 260 is made of ZnO. In one embodiment, the rear surface electrode layer 260 is patterned together with the buffer layer 250 and the light absorbing layer 240. Accordingly, in one embodiment, the rear surface electrode layer 260 has a third through-region 261.

FIGS. 8 to 11 are cross-sectional views of solar cells 300, 400, 500 and 600 according to still other embodiments of the present invention. Hereinafter, the solar cells 300, 400, 500 and 600 according to these embodiments will be described with reference to FIGS. 8 to 11.

First, as shown in FIG. 8, the solar cell 300 according to this embodiment includes a substrate 310, a back surface electrode layer 320 in which a 1a-th through-region 321 is formed, a transparent electrode layer 330 in which a 1b-th through-region 331 is formed, and a light absorbing layer 340, as described in FIG. 1. In one embodiment, the solar cell 300 further includes an adhesion improving layer 350.

Here, the adhesion improving layer 350 is interposed between the back surface electrode layer 320 and the substrate 310. According to one embodiment, the adhesion improving layer 350 is a member for improving adhesion between the substrate 310 and the back surface electrode layer 320 made of high reflection metal. In one embodiment, the adhesion improving layer 350 is formed between the substrate 310 and a portion of the back surface electrode layer 320 at which the 1a-th through-region 321 is not formed therein. In some embodiments, the adhesion improving layer 350 includes at least one of Ti, Cr, Mo and Ni. In one embodiment, the adhesion improving layer 350 is formed before the formation of the back surface electrode layer 320. In one embodiment, the adhesion improving layer 350 is patterned together with the back surface electrode layer 320 when the 1a-th through-region 321 is formed, after the formation of the back surface electrode layer 320.

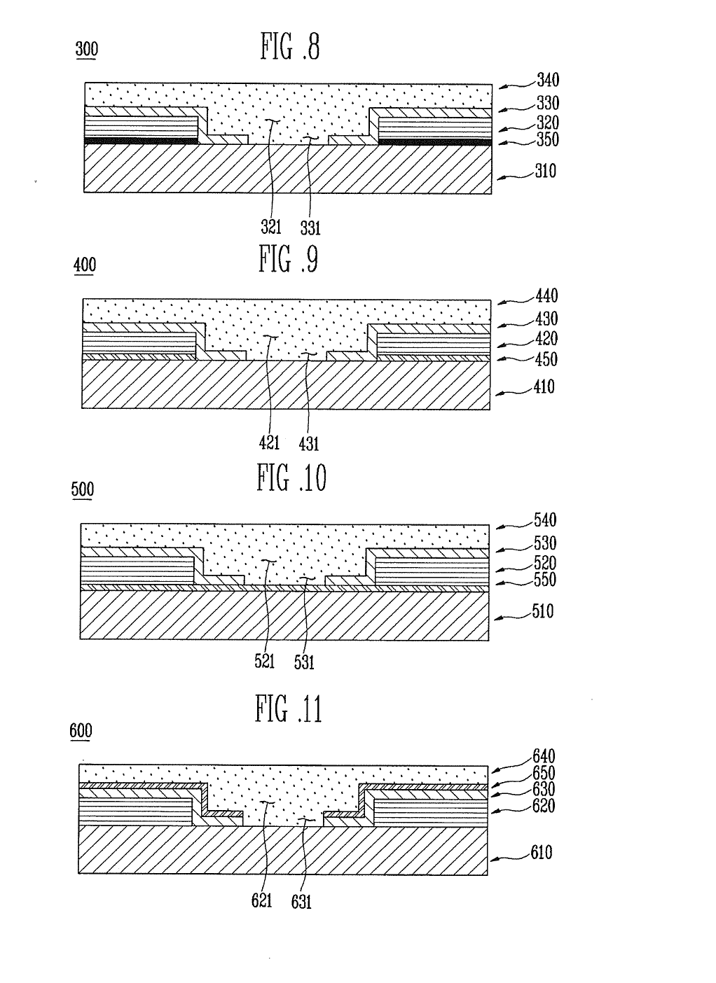

As shown in FIG. 9, the solar cell 400 according to this embodiment includes a substrate 410, a back surface electrode layer 420 in which a 1a-th through-region 421 is formed, a transparent electrode layer 430 in which a 1b-th through-region 431 is formed, and a light absorbing layer 440, as described in FIG. 1. In one embodiment, the solar cell 400 further includes a diffusion barrier layer 450.

In one embodiment, the diffusion barrier layer 450 is formed between the back surface electrode layer 420 and the substrate 410. More specifically, in one embodiment, the diffusion barrier layer 450 is formed between the substrate 410 and a portion of the back surface electrode layer at which the 1a-th through-region 421 is not formed therein. In one embodiment, the diffusion barrier layer 450 is a member for preventing (or reducing) alkali ions such as Na or K ions, or Fe ions from being diffused from the substrate 410. In one embodiment, the diffusion barrier layer 450 includes at least one an oxide and/or a nitride material such as silicon oxide, silicon nitride, silicon oxynitride, aluminum oxide, aluminum oxynitride, titanium nitride, tantalum nitride, or tungsten nitride (e.g. SiOₓ, SiNₓ, SiOₓN_{y}, Al₂O₃, AlOₓN_{y}, TiN, TaN and/or WN). In one embodiment, the diffusion barrier layer 450 is formed before the formation of the back surface electrode layer 420. In one embodiment, the diffusion barrier layer 450 is patterned together with the back surface electrode layer 420 when the 1a-th through-region 421 is formed after the formation of the back surface electrode layer 420.

As shown in FIG. 10, the solar cell 500 according to this embodiment includes a substrate 510, a back surface electrode layer 520 in which a 1a-th through-region 521 is formed, a transparent electrode layer 530 in which a 1b-th through-region 531 is formed, and a light absorbing layer 540, as described in FIG. 1. In one embodiment, the solar cell 500 further includes a diffusion barrier layer 550.

That is, the diffusion barrier layer 550 according to this embodiment is formed between the substrate 510 and the back surface electrode layer 520. Unlike FIG. 9, the diffusion barrier layer 550, in one embodiment, is also formed on the upper surface of the substrate 510 having the 1a-th through-region 521 formed thereon. In this embodiment, the diffusion barrier layer 550 is also formed on the upper surface of the substrate 510 having the 1a-th through-region 521 formed thereon, and thus it is possible to prevent impurities from being diffused through the 1a-th through-region 521. In one embodiment, the diffusion barrier layer 550 is formed before the formation of the back surface electrode layer 520. In some embodiments, the diffusion barrier layer 550 remains on the upper surface of the substrate 510 when the 1a-th through-region 521 is formed after the formation of the back surface electrode layer 520, e.g., by controlling energy of laser.

As shown in FIG. 11, the solar cell 600 according to this embodiment includes a substrate 610, a back surface electrode layer 620 in which a 1a-th through-region 621 is formed, a transparent electrode layer 630 in which a 1b-th through-region 631 is formed, and a light absorbing layer 640, as described in FIG. 1. In one embodiment, the solar cell 600 further includes a contact resistance improving layer 650.

In one embodiment, the contact resistance improving layer 650 is a member for improving contact resistance between the transparent electrode layer 630 and the light absorbing layer 640. In one embodiment, the contact resistance improving layer 650 is made of a p-type semiconductor material having a higher concentration of holes than that of the light absorbing layer 640. In one embodiment, the contact resistance improving layer 650 includes at least one of MSeₓ and MSₓ (here, M is, for example, any one of Mo, W, Ta, Nb, Ti, Cr, V or Mn). In one embodiment, the contact resistance improving layer 650 is formed between the transparent electrode layer 630 and the light absorbing layer 640. In this case, the contact resistance improving layer 650 is formed before the formation of the transparent electrode layer 630. In one embodiment, the contact resistance improving layer 650 is patterned together with the transparent electrode layer 630 when the 1b-th through-region 631 is formed.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A solar cell comprising:
a substrate;
a first electrode layer on the substrate;
a second electrode layer on the first electrode layer; and
a light absorbing layer on the second electrode layer,
wherein:
the first electrode layer has a first through-region;
the second electrode layer is a transparent electrode layer and has a second through-region; and
the second through-region is narrower than the first through-region and is at a position corresponding to the first through region.

2. The solar cell according to claim 1, wherein the second electrode layer covers an upper surface and a side surface of the first electrode layer, and wherein the side surface is inside the first through-region.

3. The solar cell according to claim 2, wherein the second electrode layer covers a portion of the upper surface of the substrate by a distance equal to a thickness of the second electrode layer.

4. The solar cell according to claim 2, wherein the second electrode layer covers a portion of the upper surface of the substrate by a distance greater than a thickness of the second electrode layer.

5. The solar cell according to claim 1, wherein the light absorbing layer contacts at least a portion of the substrate.

6. The solar cell according to claim 1, wherein the difference in a width of the first through-region and a width of the second through-region is 10 μm or more.

7. The solar cell according to claim 1, wherein the difference in a width of the first through-region and a width of the second through-region is 30 μm or more.

8. The solar cell according to claim 1, wherein the first electrode layer is a back surface electrode layer, and comprises at least one selected from Ag, Al, Cu, Au, Pt and Cr.

9. The solar cell according to claim 1, wherein the light absorbing layer comprises a Group 1-III-VI based compound semiconductor or a Group I-II-IV-VI based compound semiconductor.

10. The solar cell according to claim 1, wherein the light absorbing layer comprises at least one selected from Cu, In, Ga, S, Se, Zn, and Sn.

11. The solar cell according to claim 1, wherein the second electrode layer comprises at least one selected from zinc oxide, indium oxide, tin oxide, titanium oxide, and zinc oxide doped with one or more of Al, Ga and B.

12. The solar cell according to claim 1, wherein the second electrode layer has a thickness of at least 10 nm or a thickness of from 50 to 150 nm.

13. The solar cell according to claim 1, further comprising at least one selected from:
an adhesion improving layer between the first electrode layer and the substrate;
a diffusion barrier layer between the first electrode layer and the substrate;
a contact resistance improving layer between the second electrode layer and the light absorbing layer;
a buffer layer on the light absorbing layer; and
and a rear surface electrode layer on a buffer layer on the light absorbing layer.

14. The solar cell according to claim 13, wherein the adhesion improving layer comprises at least one selected from Ti, Cr, Mo and Ni.

15. The solar cell according to claim 13, wherein the diffusion barrier layer comprises an oxide or nitride material, and wherein the oxide or nitride material is selected from silicon oxide, silicon nitride, silicon oxynitride, aluminum oxide, aluminum oxynitride, titanium nitride, tantalum nitride, and tungsten nitride.

16. The solar cell according to claim 13, wherein the contact resistance improving layer comprises at least one of MSeₓ or MSₓ, wherein M is selected from Mo, W, Ta, Nb, Ti, Cr, V and Mn.

17. The solar cell according to claim 1, wherein the solar cell has a thickness of less than 1 μm.

18. A method of making a solar cell, the method comprising:
forming a first electrode layer on a substrate;
forming a first through-region through the first electrode layer, to expose a first portion of the substrate;
forming a second electrode layer covering the first electrode layer and the exposed first portion of the substrate; and
forming a second through-region through the second electrode layer in a region of the second electrode layer which is inside the first through region, to expose a second portion of substrate;
forming a light absorbing layer covering the second electrode layer and the exposed second portion of the substrate.

19. The method according to claim 18, wherein at least one of the forming of the through-region of the first electrode layer or the forming of the through-region of the second electrode layer comprises patterning the first electrode layer or the second electrode layer, respectively.

20. The method according to claim 18, wherein the second electrode layer is formed through a sputtering, deposition, or chemical vapor deposition (CVD) process.
